(19) United States
(12) Patent Application Publication
(10) Pub. No.: US 2012/0114868 A1
(43) Pub. Date: May 10, 2012

(54) METHOD OF FABRICATING A COMPONENT USING A FUGITIVE COATING

(75) Inventors: Ronald Scott Bunker, Waterford, NY (US); Bin Wei, Mechanicville, NY (US); Don Mark Lipkin, Niskayuna, NY (US); Raul Basilio Rebak, Schenectady, NY (US)

(73) Assignee: GENERAL ELECTRIC COMPANY, Schenectady, NY (US)

(21) Appl. No.: 12/943,563

(22) Filed: Nov. 10, 2010

(51) Int. Cl. B05D 5/00; B05D 3/02; B05D 3/00; B05D 1/18; C25F 3/00; B05D 1/00; C23C 16/44; C23C 16/50; C23C 4/12; B05D 3/12; B05D 1/04

(52) U.S. Cl. 427/448; 427/256; 427/569; 427/576; 427/458; 427/180; 427/248.1; 205/668

(57) ABSTRACT

A method of fabricating a component is provided. The method includes depositing a fugitive coating on a surface of a substrate, where the substrate has at least one hollow interior space. The method further includes machining the substrate through the fugitive coating to form one or more grooves in the surface of the substrate. Each of the one or more grooves has a base and extends at least partially along the surface of the substrate. The method further includes forming one or more access holes through the base of a respective one of the one or more grooves to connect the respective groove in fluid communication with the respective hollow interior space. The method further includes filling the one or more grooves with a filler, removing the fugitive coating, disposing a coating over at least a portion of the surface of the substrate, and removing the filler from the one or more grooves, such that the one or more grooves and the coating together define a number of channels for cooling the component.

### BACKGROUND

The invention relates generally to gas turbine engines, and, more specifically, to micro-channel cooling therein.

In a gas turbine engine, air is pressurized in a compressor and mixed with fuel in a combustor for generating hot combustion gases. Energy is extracted from the gases in a high pressure turbine (HPT), which powers the compressor, and in a low pressure turbine (LPT), which powers a fan in a turbofan aircraft engine application, or powers an external shaft for marine and industrial applications.

Engine efficiency increases with temperature of combustion gases. However, the combustion gases heat the various components along their flowpath, which in turn requires cooling thereof to achieve a long engine lifetime. Typically, the hot gas path components are cooled by bleeding air from the compressor. This cooling process reduces engine efficiency, as the bled air is not used in the combustion process.

Gas turbine engine cooling art is mature and includes numerous patents for various aspects of cooling circuits and features in the various hot gas path components. For example, the combustor includes radially outer and inner liners, which require cooling during operation. Turbine nozzles include hollow vanes supported between outer and inner bands, which also require cooling. Turbine rotor blades are hollow and typically include cooling circuits therein, with the blades being surrounded by turbine shrouds, which also require cooling. The hot combustion gases are discharged through an exhaust which may also be lined, and suitably cooled.

In all of these exemplary gas turbine engine components, thin metal walls of high strength superalloy metals are typically used for enhanced durability while minimizing the need for cooling thereof. Various cooling circuits and features are tailored for these individual components in their corresponding environments in the engine. For example, a series of internal cooling passages, or serpentines, may be formed in a hot gas path component. A cooling fluid may be provided to the serpentines from a plenum, and the cooling fluid may flow through the passages, cooling the hot gas path component substrate and coatings. However, this cooling strategy typically results in comparatively low heat transfer rates and non-uniform component temperature profiles.

Micro-channel cooling has the potential to significantly reduce cooling requirements by placing the cooling as close as possible to the heat zone, thus reducing the temperature delta between the hot side and cold side for a give heat transfer rate. However, when applying the structural coating over channels, the most critical regions are the top edges of the channels. If these edges are not sharp and at right angles, then flaws can be initiated at the interface between the substrate base metal and the structural coating, either as a gap, a crack starter, or as a small void that can propagate flaws into the coating as it is deposited.

It would therefore be desirable to provide a method for forming channels in a component with channel edges formed as sharp right angles, without further processing of the substrate base metal.

### BRIEF DESCRIPTION OF THE INVENTION

One aspect of the present invention resides in a method of fabricating a component. The method includes depositing a fugitive coating on a surface of a substrate, where the substrate has at least one hollow interior space. The method further includes machining the substrate through the fugitive coating to form one or more grooves in the surface of the substrate. Each of the one or more grooves has a base and extends at least partially along the surface of the substrate. The method further includes forming one or more access holes through the base of a respective one of the one or more grooves to connect the respective groove in fluid communication with the respective hollow interior space. The method further includes filling the one or more grooves with a filler, removing the fugitive coating, disposing a coating over at least a portion of the surface of the substrate, and removing the filler from the one or more grooves, such that the one or more grooves and the coating together define a number of channels for cooling the component.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic illustration of a gas turbine system;

FIG. 2 is a schematic cross-section of an example airfoil configuration with cooling channels, in accordance with aspects of the present invention;

FIGS. 3-10 schematically illustrate process steps for forming cooling channels in a substrate;

FIG. 11 schematically depicts, in perspective view, three example cooling channels that extend partially along the surface of the substrate and channel coolant to respective film cooling holes; and

FIG. 12 is a cross-sectional view of one of the example cooling channels of FIG. 11 and shows the channel conveying coolant from an access hole to a film cooling hole.

### DETAILED DESCRIPTION OF THE INVENTION

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The modifier “about” used in connection with a quantity is inclusive of the stated value, and has the meaning dictated by context, (e.g., includes the degree of error associated with measurement of the particular quantity). In addition, the term “combination” is inclusive of blends, mixtures, alloys, reaction products, and the like.

Moreover, in this specification, the suffix “(s)” is usually intended to include both the singular and the plural of the term that it modifies, thereby including one or more of that term (e.g., “the passage hole” may include one or more passage holes, unless otherwise specified). Reference throughout the specification to “one embodiment,” “another embodiment,” “an embodiment,” and so forth, means that a particular element (e.g., feature, structure, and/or characteristic) described in connection with the embodiment is included in at least one embodiment described herein, and may or may not be present in other embodiments. In addition, it is to be understood that the described inventive features may be combined in any suitable manner in the various embodiments.

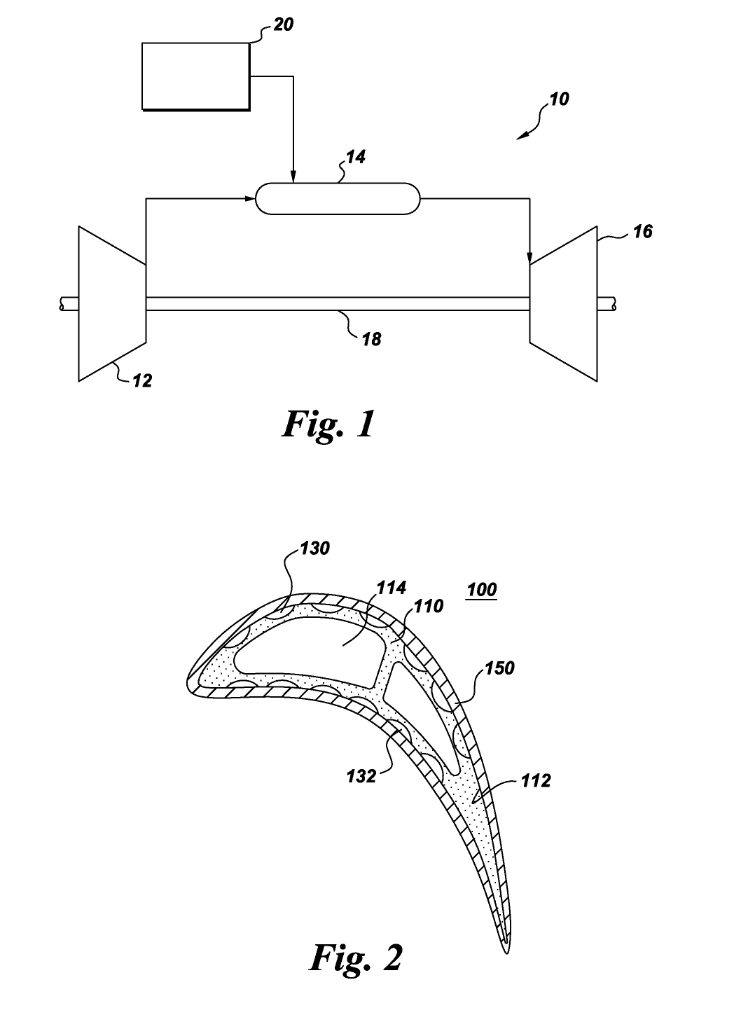

FIG. 1 is a schematic diagram of a gas turbine system 10. The system 10 may include one or more compressors 12, combustors 14, turbines 16, and fuel nozzles 20. The compressor 12 and turbine 16 may be coupled by one or more shaft 18. The shaft 18 may be a single shaft or multiple shaft segments coupled together to form shaft 18.

The gas turbine system 10 may include a number of hot gas path components 100. A hot gas path component is any component of the system 10 that is at least partially exposed to a high temperature flow of gas through the system 10. For example, bucket assemblies (also known as blades or blade assemblies), nozzle assemblies (also known as vanes or vane assemblies), shroud assemblies, transition pieces, retaining rings, and compressor exhaust components are all hot gas path components. However, it should be understood that the hot gas path component 100 of the present invention is not limited to the above examples, but may be any component that is at least partially exposed to a high temperature flow of gas. Further, it should be understood that the hot gas path component 100 of the present disclosure is not limited to components in gas turbine systems 10, but may be any piece of machinery or component thereof that may be exposed to high temperature flows.

When a hot gas path component 100 is exposed to a hot gas flow 80, the hot gas path component 100 is heated by the hot gas flow 80 and may reach a temperature at which the hot gas path component 100 fails. Thus, in order to allow system 10 to operate with hot gas flow 80 at a high temperature, increasing the efficiency and performance of the system 10, a cooling system for the hot gas path component 100 is required.

In general, the cooling system of the present disclosure includes a series of small channels, or micro-channels, formed in the surface of the hot gas path component 100. The hot gas path component may be provided with a cover layer. A cooling fluid may be provided to the channels from a plenum, and the cooling fluid may flow through the channels, cooling the cover layer.

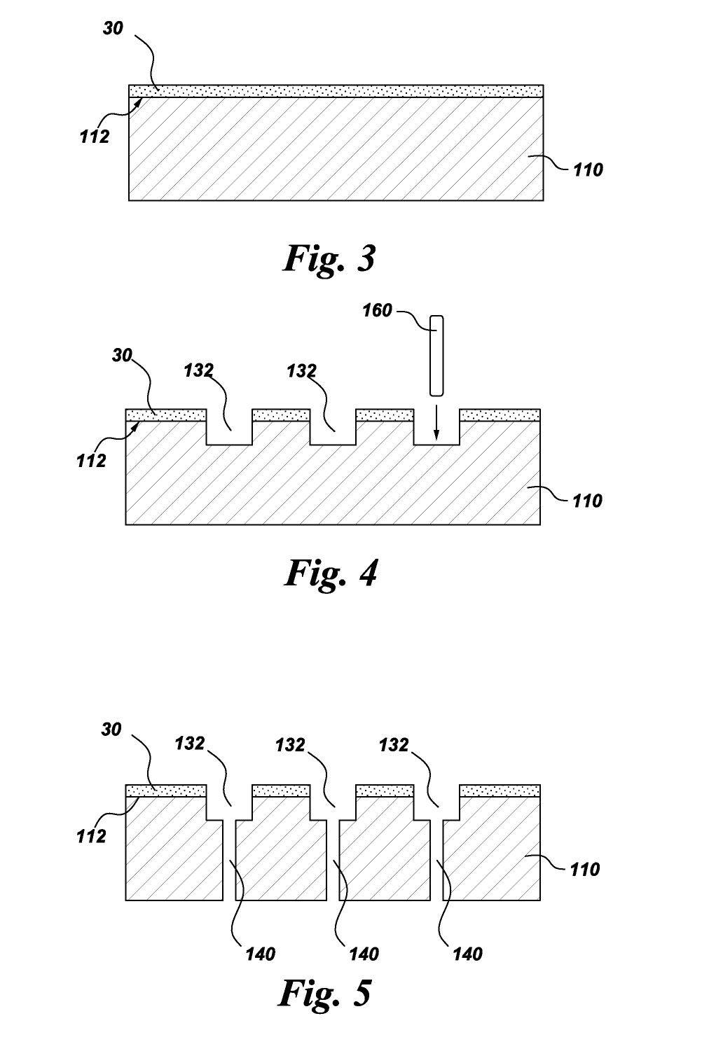

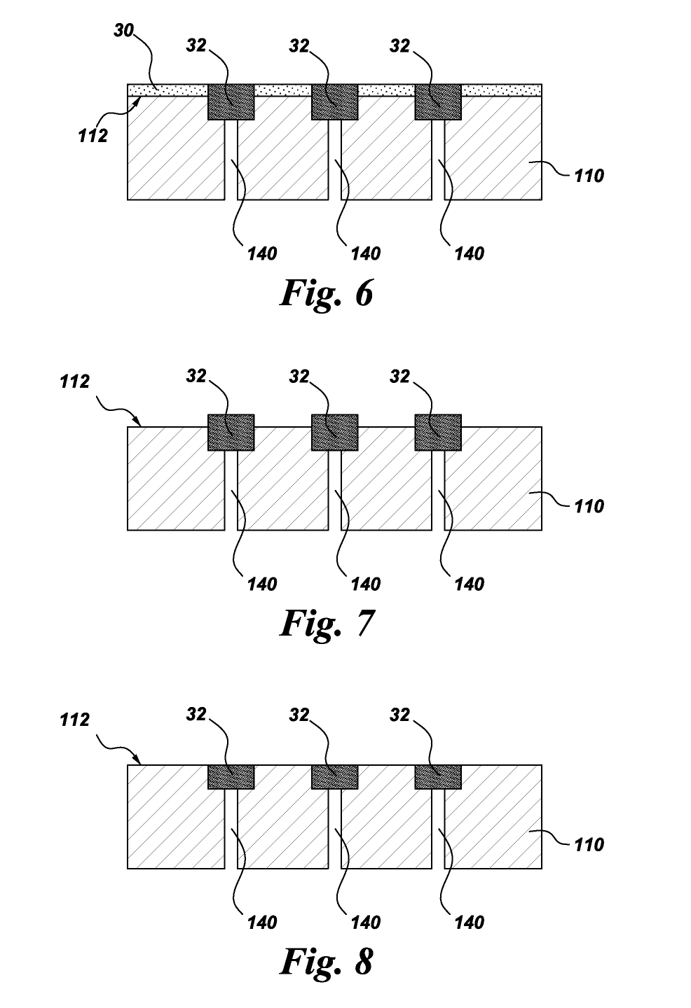

A method of fabricating a component 100 is described with reference to FIGS. 3-10. As indicated, for example, in FIG. 3, the method includes depositing a fugitive coating 30 on a surface 112 of a substrate 110. Depending on the implementation the fugitive coating may cover a portion of the surface 112 or, as shown in FIG. 3, may extend over the entire surface 110. As indicated, for example, in FIG. 2, the substrate 110 has at least one hollow interior space 114.

The substrate 110 is typically cast prior to depositing the fugitive coating 30 on the surface 112 of the substrate 110. As discussed in commonly assigned U.S. Pat. No. 5,626,462, which is incorporated by reference herein in its entirety, substrate 110 may be formed from any suitable material, described herein as a first material. Depending on the intended application for component 100, this could include Ni-base, Co-base and Fe-base superalloys. The Ni-base superalloys may be those containing both γ and γ′ phases, particularly those Ni-base superalloys containing both γ and γ′ phases wherein the γ′ phase occupies at least 40% by volume of the superalloy. Such alloys are known to be advantageous because of a combination of desirable properties including high temperature strength and high temperature creep resistance. First material may also comprise a NiAl intermetallic alloy, as these alloys are also known to possess a combination of superior properties including high temperature strength and high temperature creep resistance that are advantageous for use in turbine engine applications used for aircraft. In the case of Nb-base alloys, coated Nb-base alloys having superior oxidation resistance will be preferred, such as Nb/Ti alloys, and particularly those alloys comprising Nb-(27-40)Ti-(4.5-10.5)Al-(4.5-7.9)Cr-(1.5-5.5) Hf-(0-6)V in an atom percent. First material may also comprise a Nb-base alloy that contains at least one secondary phase, such as a Nb-containing intermetallic compound, a Nb-containing carbide or a Nb-containing boride. Such alloys are analogous to a composite material in that they contain a ductile phase (i.e. the Nb-base alloy) and a strengthening phase (i.e. a Nb-containing intermetallic compound, a Nb-containing carbide or a Nb-containing boride).

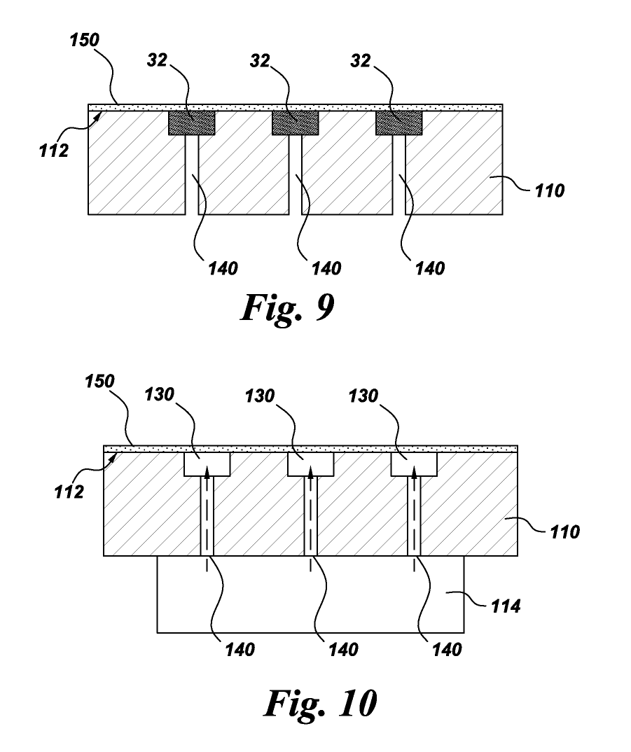

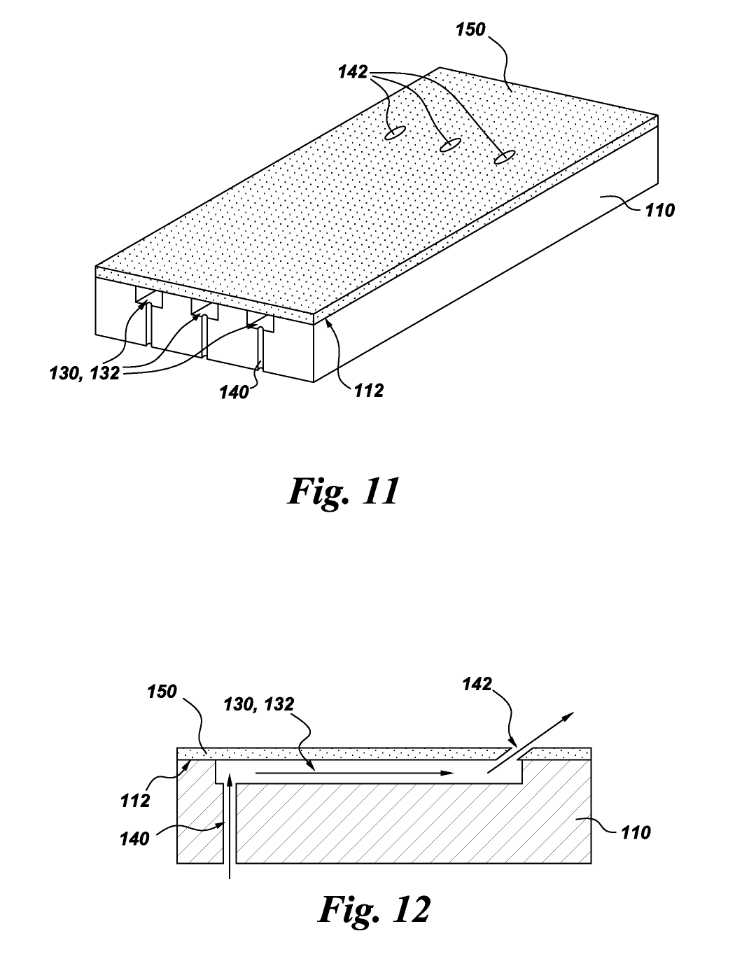

As indicated, for example, in FIG. 4, the method further includes machining the substrate 110 through the fugitive coating 30 to form one or more grooves 132 in the surface 112 of the substrate 110. For the illustrated examples, multiple grooves 132 are formed in the substrate 110. As indicated in FIG. 4, each of the grooves 132 has a base 134 and, as shown for example in FIGS. 11 and 12, extends at least partially along the surface 112 of the substrate 110. Although the grooves are shown as having straight walls, the grooves 132 can have any configuration, for example, they may be straight, curved, or have multiple curves, etc. For the examples shown in FIGS. 11 and 12, the grooves convey fluid to exiting film holes 142. However, other configurations do not entail a film hole, with the channels simply extending along the substrate surface 112 and exiting off an edge of the component, such as the trailing edge or the bucket tip, or an endwall edge. In addition, it should be noted that although the film holes are shown in FIG. 11 as being round, this is simply a non-limiting example. The film holes may also be non-circular shaped holes.

The grooves 132 may be formed using a variety of techniques. For example, the grooves 132 may be formed using one or more of an abrasive liquid jet, plunge electrochemical machining (ECM), electric discharge machining with a spinning single point electrode (milling EDM), and laser machining (laser drilling). Example laser machining techniques are described in commonly assigned, U.S. patent application Ser. No. 12/697,005, “Process and system for forming shaped air holes” filed Jan. 29, 2010, which is incorporated by reference herein in its entirety. Example EDM techniques are described in commonly assigned U.S. patent application Ser. No. 12/790,675, “Articles which include chevron film cooling holes, and related processes,” filed May 28, 2010, which is incorporated by reference herein in its entirety.

For particular process configurations, one or more grooves 132 are formed by directing an abrasive liquid jet 160 at the surface 112 of the substrate 110, as schematically depicted in FIG. 4. Beneficially, any rounding of the channel edges will be in the fugitive material, not in the substrate base metal. Example water jet drilling processes and systems are provided in commonly assigned U.S. patent application Ser. No. 12/790,675, “Articles which include chevron film cooling holes, and related processes,” filed May 28, 2010, which is incorporated by reference herein in its entirety. As explained in U.S. patent application Ser. No. 12/790,675, the water jet process typically utilizes a high-velocity stream of abrasive particles (e.g., abrasive “grit”), suspended in a stream of high pressure water. The pressure of the water may vary considerably, but is often in the range of about 5,000-90,000 psi. A number of abrasive materials can be used, such as garnet, aluminum oxide, silicon carbide, and glass beads. Beneficially, the water jet process does not involve heating of the substrate 110 to any significant degree. Therefore, there is no “heat-affected zone” formed on the substrate surface 112, which could otherwise adversely affect the desired exit geometry for the grooves 132.

In addition, and as explained in U.S. patent application Ser. No. 12/790,675, the water jet system can include a multi-axis computer numerically controlled (CNC) unit. The CNC systems themselves are known in the art, and described, for example, in U.S. Patent Publication 2005/0013926 (S. Rutkowski et al), which is incorporated herein by reference. CNC systems allow movement of the cutting tool along a number of X, Y, and Z axes, as well as rotational axes.

As indicated, for example, in FIG. 5, the method further includes forming one or more access holes 140. More particularly, one or more access holes 140 are provided per groove 132. For the illustrated examples, one access hole 140 is provided per groove 132. As indicated, for example, in FIG. 10, each of the access holes 140 is formed through the base 134 of a respective one of the grooves 132, to connect the groove 132 in fluid communication with respective ones of the hollow interior space(s) 114. As indicated, for example, in FIG. 10, the access holes 140 connect respective ones of the grooves 132 in fluid communication with respective ones of the at least one hollow interior space 114. The one or more access holes 140 are typically circular or oval in cross-section and may be formed, for example using on or more of laser machining (laser drilling), abrasive liquid jet, electric discharge machining (EDM) and electron beam drilling The access holes 140 may be normal to the base 134 of the respective grooves 132 (as shown in FIG. 6) or may be drilled at angles in a range of 20-90 degrees relative to base 134 of the groove 132.

As indicated, for example, in FIG. 6, the method further includes filling the one or more grooves 132 with a filler 32. For example, the filler may be applied by slurry, dip coating or spray coating the component 100 with a metallic slurry “ink” 32, such that the grooves 132 are filled. For other configurations, the filler 32 may be applied using a micro-pen or syringe. For certain implementations, the grooves 132 may be over-filled with the filler material 32. Excess filler 32 may be removed, for example may be wiped off, such that the grooves 132 are “seen.” Non-limiting example materials for the filler 32 include photo-curable resins (for example, visible or UV curable resins), ceramics, copper or molybdenum inks with an organic solvent carrier, and graphite powder with a water base and a carrier. More generally, the filler 32 may comprise the particles of interest suspended in a carrier with an optional binder. Further, depending on the type of filler employed, the filler may or may not flow into the access holes 140. Example filler materials (or channel filling means or sacrificial materials) are discussed in commonly assigned, U.S. Pat. No. 5,640,767 and in commonly assigned, U.S. Pat. No. 6,321,449, which are incorporated by reference herein in their entirety. For particular process configurations, a low strength metallic slurry “ink” is used for the filler. The use of a low strength ink beneficially facilitates subsequent polishing. In addition, for certain process configurations, the filler is filled above the channel height due to the first fugitive coating thickness, such that the filler will cure down to the desired height or a bit taller.

As indicated, for example, in FIG. 9, the method further includes disposing a coating 150 over at least a portion of the surface 112 of the substrate 110. It should be noted that as depicted, coating 150 is just the first coating or structural coating that covers the channels. For certain applications, a single coating may be all that is used. However, for other applications, a bondcoat and a thermal barrier coating (TBC) are also used. Example coatings 150 are provided in U.S. Pat. No. 5,640,767 and U.S. Pat. No. 5,626,462, which are incorporated by reference herein in their entirety. As discussed in U.S. Pat. No. 5,626,462, the coatings 150 are bonded to portions of the surface 112 of the substrate 110.

For the example arrangement illustrated in FIG. 2, coating 150 extends longitudinally along airfoil-shaped outer surface 112 of substrate 110. Coating 150 conforms to airfoil-shaped outer surface 112 and covers grooves 132 forming channels 130. As indicated in FIGS. 11 and 12, for example, the substrate 110 and coating 150 may further define one or more exit film holes 142. More generally, the substrate 110 and the coating may define a number of exit holes to convey fluid from the channels 130 to the exterior surface of the component 100. For the example configuration shown in FIG. 12, the channel 130 conveys coolant from an access hole 140 to a film cooling hole 142. Coating 150 comprises a second material, which may be any suitable material and is bonded to the airfoil-shaped outer surface 120 of substrate 110. For particular configurations, the coating 150 has a thickness in the range of 0.1-2.0 millimeters, and more particularly, in the range of 0.1 to 1 millimeters, and still more particularly 0.1 to 0.5 millimeters for industrial components. For aviation components, this range is typically 0.1 to 0.25 millimeters. However, other thicknesses may be utilised depending on the requirements for a particular component 100.

Referring again to FIGS. 6 and 7, for particular process configurations, the method further includes removing the fugitive coating 30 prior to disposing the coating 150 over the surface 112 of the substrate 110. Depending on the specific materials and processes, the fugitive coating 30 may be removed using mechanical (for example, polishing) or chemical (for example, dissolution in a solvent) means or using a combination thereof. The coating 150 may be deposited using a variety of techniques. For particular processes, the coating 150 is disposed over at least a portion of the surface 112 of the substrate 110 by performing an ion plasma deposition. Example cathodic arc ion plasma deposition apparatus and method are provided in commonly assigned, US Published Patent Application No. 20080138529, Weaver et al, “Method and apparatus for cathodic arc ion plasma deposition,” which is incorporated by reference herein in its entirety. Briefly, ion plasma deposition comprises placing a cathode formed of a coating material into a vacuum environment within a vacuum chamber, providing a substrate 110 within the vacuum environment, supplying a current to the cathode to form a cathodic arc upon a cathode surface resulting in erosion or evaporation of coating material from the cathode surface, and depositing the coating material from the cathode upon the substrate surface 112.

In one non-limiting example, the ion plasma deposition process comprises a plasma vapor deposition process. Non-limiting examples of the coating 150 include structural coatings, bond coatings, oxidation-resistant coatings, and thermal barrier coatings, as discussed in greater detail below with reference to U.S. Pat. No. 5,626,462. For certain hot gas path components 100, the coating 150 comprises a nickel-based or cobalt-based alloy, and more particularly comprises a superalloy or a NiCoCrAlY alloy. For example, where the first material of substrate 110 is a Ni-base superalloy containing both γ and γ′ phases, coating 150 may comprise these same materials, as discussed in greater detail below with reference to U.S. Pat. No. 5,626,462.

For other process configurations, the coating 150 is disposed over at least a portion of the surface 112 of the substrate 110 by performing at least one of a thermal spray process and a cold spray process. For example, the thermal spray process may comprise combustion spraying or plasma spraying, the combustion spraying may comprise high velocity oxygen fuel spraying (HVOF) or high velocity air fuel spraying (HVAF), and the plasma spraying may comprise atmospheric (such as air or inert gas) plasma spray, or low pressure plasma spray (LPPS, which is also know as vacuum plasma spray or VPS). In one non-limiting example, a NiCrAlY coating is deposited by HVOF or HVAF. Other example techniques for depositing one or more layers of the coating 150 include, without limitation, sputtering, electron beam physical vapor deposition, electroless plating, and electroplating.

For certain configurations, it is desirable to employ multiple deposition techniques for forming the coating system 150. For example, a first coating layer may be deposited using an ion plasma deposition, and a subsequently deposited layer and optional additional layers (not shown) may be deposited using other techniques, such as a combustion spray process (for example HVOF or HVAF) or using a plasma spray process, such as LPPS. Depending on the materials used, the use of different deposition techniques for the coating layers may provide benefits in strain tolerance and/or in ductility.

More generally, and as discussed in U.S. Pat. No. 5,626,462, the second material used to form coating 150 comprises any suitable material. For the case of a cooled turbine component 100, the second material must be capable of withstanding temperatures up to about 1150° C., while the TBC can withstand temperatures up to about 1320° C. The coating 150 must be compatible with and adapted to be bonded to the airfoil-shaped outer surface 112 of substrate 110. This bond may be formed when the coating 150 is deposited onto substrate 110. This bonding may be influenced during the deposition by many parameters, including the method of deposition, the temperature of the substrate 110 during the deposition, whether the deposition surface is biased relative to the deposition source, and other parameters. Bonding may also be affected by subsequent heat treatment or other processing. In addition, the surface morphology, chemistry and cleanliness of substrate 110 prior to the deposition can influence the degree to which metallurgical bonding occurs. In addition to forming a strong metallurgical bond between coating 150 and substrate 110, it is desirable that this bond remain stable over time and at high temperatures with respect to phase changes and interdiffusion, as described herein. By compatible, it is preferred that the bond between these elements be thermodynamically stable such that the strength and ductility of the bond do not deteriorate significantly over time (e.g. up to 3 years) by interdiffusion or other processes, even for exposures at high temperatures on the order of 1,150° C., for Ni-base alloy airfoil support walls 40 and Ni-base airfoil skins 42, or higher temperatures on the order of 1,300° C. in the case where higher temperature materials are utilized, such as Nb-base alloys.

As discussed in U.S. Pat. No. 5,626,462, where the first material of substrate 110 is an Ni-base superalloy containing both γ and γ′ phases or a NiAl intermetallic alloy, second materials for coating 150 may comprise these same materials. Such a combination of coating 150 and substrate 110 materials is preferred for applications such as where the maximum temperatures of the operating environment similar to those of existing engines (e.g. below 1650° C.). In the case where the first material of substrate 110 is an Nb-base alloys, second materials for coating 150 may also comprise an Nb-base alloy, including the same Nb-base alloy.

As discussed in U.S. Pat. No. 5,626,462, for other applications, such as applications that impose temperature, environmental or other constraints that make the use of a metal alloy coating 150 undesirable, it is preferred that coating 150 comprise materials that have properties that are superior to those of metal alloys alone, such as composites in the general form of intermetallic compound (Iₛ)/metal alloy (M) phase composites and intermetallic compound (Iₛ)/intermetallic compound (I_{M}) phase composites. Metal alloy M may be the same alloy as used for airfoil support wall 40, or a different material, depending on the requirements of the airfoil. These composites are generally speaking similar, in that they combine a relatively more ductile phase M or I_{M} with a relatively less ductile phase Iₛ, in order to create a coating 150 that gains the advantage of both materials. Further, in order to have a successful composite, the two materials must be compatible. As used herein in regard to composites, the term compatible means that the materials must be capable of forming the desired initial distribution of their phases, and of maintaining that distribution for extended periods of time as described above at use temperatures of 1,150° C. or more, without undergoing metallurgical reactions that substantially impair the strength, ductility, toughness, and other important properties of the composite. Such compatibility can also be expressed in terms of phase stability. That is, the separate phases of the composite must have a stability during operation at temperature over extended periods of time so that these phases remain separate and distinct, retaining their separate identities and properties and do not become a single phase or a plurality of different phases due to interdiffusion. Compatibility can also be expressed in terms of morphological stability of the interphase boundary interface between the I_{S}/M or I_{S}/I_{M} composite layers. Such instability may be manifested by convolutions, which disrupt the continuity of either layer. It is also noted that within a given coating 150, a plurality of I_{S}/M or I_{S}/I_{M} composites may also be used, and such composites are not limited to two material or two phase combinations. The use of such combinations are merely illustrative, and not exhaustive or limiting of the potential combinations. Thus M/I_{M}/I_{S}, M/I_{S1}/I_{S2} (where I_{S1} and I_{S2} are different materials) and many other combinations are possible.

As discussed in U.S. Pat. No. 5,626,462, where substrate 110 comprises a Ni-base superalloy comprising a mixture of both γ and γ′ phases, Iₛ may comprise Ni₃ [Ti, Ta, Nb, V], NiAl, Cr₃ Si, [Cr, Mo]ₓ Si, [Ta, Ti, Nb, Hf, Zr, V]C, Cr₃ C₂ and Cr₇ C₃ intermetallic compounds and intermediate phases and M may comprise a Ni-base superalloy comprising a mixture of both γ and γ′ phases. In Ni-base superalloys comprising a mixture of both γ and γ′ phases, the elements Co, Cr, Al, C and B are nearly always present as alloying constituents, as well as varying combinations of Ti, Ta, Nb, V, W, Mo, Re, Hf and Zr. Thus, the constituents of the exemplary I_{S} materials described correspond to one or more materials typically found in Ni-base superalloys as may be used as first material (to form the substrate 110), and thus may be adapted to achieve the phase and interdiffusional stability described herein. As an additional example in the case where the first material (the substrate 110) comprises NiAl intermetallic alloy, I_{S} may comprise Ni₃ [Ti, Ta, Nb, V], NiAl, Cr₃ Si, [Cr, Mo]ₓ Si, [Ta, Ti, Nb, Hf, Zr, V]C, Cr₃ C₂ and Cr₇ C₃ intermetallic compounds and intermediate phases and I_{M} may comprise a Ni₃ Al intermetallic alloy. Again, in NiAl intermetallic alloys, one or more of the elements Co, Cr, C and B are nearly always present as alloying constituents, as well as varying combinations of Ti, Ta, Nb, V, W, Mo, Re, Hf and Zr. Thus, the constituents of the exemplary I_{S} materials described correspond to one or more materials typically found in NiAl alloys as may be used as first material, and thus may be adapted to achieve the phase and interdiffusional stability described herein.

As discussed in U.S. Pat. No. 5,626,462, where substrate 110 comprises a Nb-base alloy, including a Nb-base alloy containing at least one secondary phase, I_{S} may comprise a Nb-containing intermetallic compound, a Nb-containing carbide or a Nb-containing boride, and M may comprise a Nb-base alloy. It is preferred that such I_{S}/M composite comprises an M phase of an Nb-base alloy containing Ti such that the atomic ratio of the Ti to Nb (Ti/Nb) of the alloy is in the range of 0.2-1, and an I_{S} phase comprising a group consisting of Nb-base silicides, Cr₂ [Nb, Ti, Hf], and Nb-base aluminides, and wherein Nb, among Nb, Ti and Hf, is the primary constituent of Cr₂ [Nb, Ti, Hf] on an atomic basis. These compounds all have Nb as a common constituent, and thus may be adapted to achieve the phase and interdiffusional stability described in U.S. Pat. No. 5,626,462.

Referring now to FIG. 10, the method further includes removing the sacrificial filler 32 from the grooves 132, such that the grooves 132 and the coating 150 together define a number of channels 130 for cooling the component 100. For example, the filler 32 may be leached out of the channels 130 using a chemical leaching process. As discussed in U.S. Pat. No. 5,640,767, the filler (or channel filling means) may be removed by melting/extraction, pyrolysis, or etching, for example. Similarly, the filler materials (sacrificial materials) discussed in U.S. Pat. No. 6,321,449 may be removed by dissolution in water, alcohol, acetone, sodium hydroxide, potassium hydroxide or nitric acid.

In addition to coating system 150, the interior surface of the channel 130 can be further modified to improve its oxidation and/or hot corrosion resistance. Suitable techniques for applying an oxidation-resistant coating (not expressly shown) to the interior surface of the grooves 132 (or of the channels 130) include vapor-phase or slurry chromizing, vapor-phase or slurry aluminizing, or overlay deposition via evaporation, sputtering, ion plasma deposition, thermal spray, and/or cold spray. Example oxidation-resistant overlay coatings include materials in the MCrAlY family (M={Ni,Co,Fe}) as well as materials selected from the NiAlX family (X={Cr,Hf,Zr,Y,La,Si,Pt,Pd}). If used, the oxidation-resistant coating would typically be applied, using one or more of vapor phase or slurry chromizing and slurry aluminizing, to the interior surface of the channel 130. after the sacrificial filler 32 has been removed.

For the example arrangements illustrated in FIGS. 11 and 12, the channels 130 channel the cooling flow from the respective access hole 140 to the exiting film hole 142. Typically, the channel length is in the range of 10 to 1000 times the film hole diameter, and more particularly, in the range of 20 to 100 times the film hole diameter. Beneficially, the channels 130 can be used anywhere on the surfaces of the components (airfoil body, lead edges, trail edges, blade tips, endwalls, platforms). In addition, although the channels are shown as having straight walls, the channels 130 can have any configuration, for example, they may be straight, curved, or have multiple curves, etc.

Referring now to FIG. 3, for particular process configurations, the thickness of the fugitive coating 30 deposited on the surface 112 of the substrate 110 is in a range of 0.5-2.0 millimeters. In one non-limiting example, the fugitive coating 30 comprises a one millimeter thick polymer based coating. The fugitive coating 30 may be deposited using a variety of deposition techniques, including powder coating, electrostatic coating, dip-coating, spin coating, chemical vapor deposition and application of a prepared tape. More particularly, the fugitive coating is essentially uniform and is able to adhere, but does not harm the substrate base metal.

For particular process configurations, the fugitive coating 30 is deposited using powder coating or electrostatic coating. For example process configurations, the fugitive coating 30 comprises a polymer. For example, the fugitive coating 30 may comprise a polymer based coating, such as pyridine, which may be deposited using chemical vapor deposition. Other example polymer based coating materials include resins, such as polyester or epoxies. Example resins include photo-curable resins, such as a light curable or UV curable resin, non-limiting examples of which include a UV/Visible light curable masking resin, marketed under the trademark Speedmask 729® by DYMAX, having a place of business in Torrington, Conn., in which case, the method further includes curing the photo-curable resin 30, prior to forming the grooves 132. For other process configurations, the fugitive coating 30 may comprise a carbonaceous material. For example, the fugitive coating 30 may comprise graphite paint. Polyethylene is yet another example coating material. For other process configurations, the fugitive coating 30 may be enameled onto the surface 112 of the substrate 110.

Referring again to FIGS. 3 and 4, for particular process configurations, the method further includes curing the fugitive coating 30 prior to machining the substrate 110. The fugitive coating 30 acts as the machining mask for formation of the channels. This mask leads to the desired sharp channel edges. Thus, the presence of the fugitive coating during the machining operations to form the grooves 132 facilitates the formation of cooling channels 130 with the requisite sharp, well defined edges at the coating interface. This is the single most critical region in the cooling concept, and the above described fabrication process achieves the desired outcome with less precision of machining and less intricacy of filling than would be required without the use of a fugitive coating.

Although not expressly illustrated, for particular process configurations, the method further includes removing the fugitive coating 30 prior to filling the grooves with the filler 32. The coating 30 may be removed using a variety of techniques, non-limiting examples of which include chemical removal (for example, leaching) or mechanical removal (for example, by polishing). Removal of the fugitive coating removes any excess filler on the fugitive coating and beneficially leaves sharp channel edges in the substrate base metal, as the fugitive coating masked the abrasive liquid jet (for example) during formation of the grooves. The removal process should not affect the sacrificial filler. The method may further include polishing the surface to remove any excess sacrificial filler prior to deposition of the coating system 150.

For other process configurations, such as those shown in FIGS. 6 and 7, the filler is deposited and cured prior to removal of the fugitive coating. Beneficially, this facilitates the filling of the grooves prior to application of the structural coating, as a fugitive coating is present to mask the substrate base metal and act as a guide or template for a convenient filling process. For example, the method may optionally include the step of curing the filler 32, for the example process configuration shown in FIG. 6. For example, for fillers 32 comprising photo-curable resins, the filler is cured by application of light. For ceramic fillers, the filler 32 is cured by heat treatment to remove the carrier solution. For fillers comprising copper or molybdenum inks with an organic solvent carrier, the filler is cured by heat treatment to remove the carrier. For certain implementations, the curing process may effectively remove the fugitive coating 30. For example, if the sintering temperature exceeds 600° Celsius, the curing step will remove a polymer mask 30 from the substrate 110.

Because the sacrificial filler 32 may be filled above the channel height due to the thickness of the fugitive coating 30 (as indicated, for example in FIGS. 6 and 7), the filler 32 will cure down to the desired height or somewhat taller than desired. The surface 112 of the substrate 110 may then be polished to remove the excess filler, prior to deposition of the coating 150. If the curing process causes too much shrinkage of the sacrificial filler and causes the filler to pull away from the channel walls, additional filler may be added prior to removal of the fugitive coating. As discussed in commonly assigned U.S. Pat. No. 6,32,449, which is incorporated by reference herein in its entirety, suitable sacrificial fillers 32, for use in nickel-base superalloy substrates 110, exhibit: (a) compositional compatibility with nickel-base superalloys at temperatures required to deposit the coating (in the case of an airfoil 100, an airfoil skin) 150, e.g., at least 400° C. for ion plasma deposition; (b) thermal stability at coating (airfoil skin) 150 deposition temperatures; (c) ease of removal after coating (skin) deposition; (d) adhesion to a nickel-based substrate 110 at low and high temperatures prior to and during coating (skin) deposition, respectively; (e) minimal densification shrinkage relative to a nickel-based substrate 110 as the filler 32 is heated during coating (skin) deposition; (f) a comparable coefficient of thermal expansion (CTE) to nickel-based superalloys; (g) ease of removal from the substrate 110 prior to coating (skin) deposition so that the coating (skin) 150 is deposited and bonded directly to the substrate 110; and (h) formable to completely fill the grooves 132 and achieve a smooth, reasonably dense fill surface on which the coating (skin) 150 is deposited. If any of items (d) through (h) is not met, a gap may be present within the groove during skin deposition, which, if sufficiently large, will lead to an unacceptable defect in the coating (airfoil skin).

For the process illustrated in FIGS. 6 and 7, the method further includes removing the fugitive coating 30 after drying, curing or sintering the filler 32 (collectively termed “curing” the filler) and prior to disposing the coating 150 over the surface 112 of the substrate 110. For example, the removal of the fugitive coating 30 and polishing the surface 112 of the substrate 110 (to remove any excess dried, cured or sintered —collectively “cured”—filler 32) could be performed in a single step. For other implementations, two separate steps may be employed to remove the fugitive coating 30 and to polish the surface 112 of the substrate 110 to remove any excess cured filler 32.

### EXAMPLE

An example sequence of process steps is as follows. However, this is an example and is not intended to limit the invention. A fugitive coating comprising a Speedmask 729® UV/Visible light curable masking resin was applied to the surface of a single crystal superalloy (Renee N5) substrate. Grooves were formed in the substrate through the fugitive coating using an abrasive water jet. A filler material comprising copper ink was applied as a slurry over the entire surface of the fugitive coated substrate and inside the grooves. The excess filler was wiped off, and the remaining filler was then cured. The maskant (fugitive coating) was removed by performing a heat treatment at 500 degrees Celsius without harming the filler in the channels, but removing any excess filler on the maskant. The remaining cured filler in the channels was then smoothed off flush by grinding the surface. The final metallic bond coat and YSZ (Yttria-stabilised zirconia) thermal barrier coatings were applied using a HVOF process, and the filler was leached out using concentrated nitric acid.

Beneficially, the above-described method enables the formation of cooling channels, with channel edges formed as sharp right angles, without the need for further processing of the substrate base metal. These sharp channel edges reduce the likelihood of the initiation of flaws (for example a gap, a crack starter or a small void that could propagate flaws into the structural coating as it is deposited) at the interface between the substrate base metal and the structural coating. In addition, the present technique facilitates the filling of the grooves prior to application of the structural coating, as a fugitive coating is present to mask the substrate base metal and act as a guide or template for a convenient filling process.

Although only certain features of the invention have been illustrated and described herein, many modifications and changes will occur to those skilled in the art. It is, therefore, to be understood that the appended claims are intended to cover all such modifications and changes as fall within the true spirit of the invention.

1. A method of fabricating a component, the method comprising:
depositing a fugitive coating on a surface of a substrate, wherein the substrate has at least one hollow interior space;
machining the substrate through the fugitive coating to form one or more grooves in the surface of the substrate, wherein each of the one or more grooves has a base and extends at least partially along the surface of the substrate;
forming one or more access holes through the base of a respective one of the one or more grooves to connect the respective groove in fluid communication with the respective hollow interior space;
filling the grooves with a filler;
removing the fugitive coating;
disposing a coating over at least a portion of the surface of the substrate; and
removing the filler from the one or more grooves, such that the one or more grooves and the coating together define a one or more channels for cooling the component.

2. The method of claim 1, further comprising casting the substrate prior to depositing the fugitive coating on the surface of the substrate.

3. The method of claim 1, wherein the one or more grooves are formed using one or more of an abrasive liquid jet, plunge electrochemical machining (ECM), electric discharge machining with a spinning electrode (milling EDM), and laser machining (laser drilling).

4. The method of claim 1, wherein the one or more grooves are formed by directing an abrasive liquid jet at the surface of the substrate.

5. The method of claim 1, wherein disposing the coating over at least the portion of the surface of the substrate comprises performing an ion plasma deposition.

6. The method of claim 5, wherein the coating comprises a nickel-based or cobalt-based alloy.

7. The method of claim 1, wherein disposing the coating over at least the portion of the surface of the substrate comprises performing at least one of a thermal spray process and a cold spray process.

8. The method of claim 7, wherein the thermal spray process comprises high velocity oxygen fuel spraying (HVOF), high velocity air fuel spraying (HVAF), atmospheric plasma spraying, or low pressure plasma spraying (LPPS).

9. The method of claim 1, wherein a thickness of the fugitive coating deposited on the surface of the substrate is in a range of 0.1—2.0 millimeters.

10. The method of claim 1, wherein the fugitive coating comprises a polymer.

11. The method of claim 10, wherein the fugitive coating comprises a resin.

12. The method of claim 1, wherein the fugitive coating comprises a carbonaceous material.

13. The method of claim 1, further comprising drying, curing or sintering the fugitive coating prior to machining the substrate.

14. The method of claim 1, further comprising:
drying, curing, or sintering the filler; and
removing the fugitive coating after drying, curing or sintering the filler and prior to disposing the coating over the surface of the substrate.

15. The method of claim 1, further comprising removing the fugitive coating prior to filling the one or more grooves with the filler.

16. The method of claim 1, wherein the fugitive coating is deposited using a deposition technique selected from the group consisting of powder coating, electrostatic coating, dip-coating, spin coating, chemical vapor deposition and application of a prepared tape.

17. The method of claim 16, wherein the fugitive coating is deposited using powder coating or electrostatic coating.
